(19) United States
(12) Patent Application Publication
(10) Pub. No.: US 2026/0114206 A1
(43) Pub. Date: Apr. 23, 2026

(54) WAFER PROCESSING APPARATUS AND METHOD OF USING THE SAME

(71) Applicant: SAMSUNG ELECTRONICS CO., LTD., Suwon-si (KR)

(72) Inventors: Seunghun Kim, Suwon-si (KR); Taejin Kwak, Suwon-si (KR); Youngkwon Kim, Suwon-si (KR); Taemin Kim, Suwon-si (KR); Jiho Uh, Suwon-si (KR); Geongu Jang, Suwon-si (KR); Yujin Han, Suwon-si (KR)

(73) Assignee: SAMSUNG ELECTRONICS CO., LTD., Suwon-si (KR)

(21) Appl. No.: 19/233,431

(22) Filed: Jun. 10, 2025

(30) Foreign Application Priority Data
Oct. 17, 2024 (KR) 10-2024-0142474

(51) Int. Cl. H01L 21/67

(52) U.S. Cl. CPC H10P 72/0402; H10P 72/0604

(57) ABSTRACT

A wafer processing apparatus, may include: a heating furnace configured to contain wafers disposed along a first direction; discharge fluid lines having at least parts in an interior of the heating furnace and configured to discharge a reaction gas into the interior of the heating furnace; a gas distributor connected to the discharge fluid lines, and configured to distribute the reaction gas to the discharge fluid lines; a first side region of the interior of the heating furnace on a first side of the interior of the heating furnace with respect to the first direction; and a second side region of the interior of the heating furnace on a second side of the interior of the heating furnace with respect to the first direction.

### CROSS-REFERENCE TO RELATED APPLICATION

This application claims priority to and the benefit of Korean Patent Application No. 10-2024-0142474 filed in the Korean Intellectual Property Office on Oct. 17, 2024, the entire contents of which is incorporated herein by reference.

### BACKGROUND

### (a) Field

The present disclosure relates to a wafer processing apparatus and a method of using the same, and more particularly, to a wafer processing apparatus using a reaction gas and a method of using the same.

### (b) Description of the Related Art

The semiconductor manufacturing process includes various wafer processing processes, such as wafer etching and diffusion processes. In the diffusion process, the reaction gas may be supplied to the wafer to deposit an impurity element on the wafer.

In the diffusion process, a batch-type facility may be used in which a plurality of wafers are placed inside a heating furnace using a boat or the like and subjected to reaction processing with the reaction gas.

When a plurality of wafers are subjected to reaction processing in the interior of the heating furnace through the batch-type facility, it is important to reduce the thickness deviation among the plurality of wafers by uniformly supplying the reaction gas to the plurality of wafers in the interior of the heating furnace.

### SUMMARY

One or more embodiments attempt to provide a wafer processing apparatus and a method of using the same, capable of effectively decreasing a thickness deviation among a plurality of wafers.

One or more embodiments attempt to provide a wafer processing apparatus and a method of using the same, capable of supplying the reaction gas to interior of the heating furnace effectively and uniformly.

One or more embodiments attempt to provide a wafer processing apparatus and a method of using the same, capable of supplying the reaction gas to the interior of the heating furnace uniformly and efficiently while minimizing an unnecessary facility increase.

One or more embodiments attempt to provide a wafer processing apparatus and a method of using the same, capable of effectively improving the uniformity of the reaction gas inside the heating furnace internal according to the reaction processing result.

According to one or more example embodiments, a wafer processing apparatus, may include: a heating furnace configured to contain wafers disposed along a first direction; discharge fluid lines having at least parts in an interior of the heating furnace and configured to discharge a reaction gas into the interior of the heating furnace; a gas distributor connected to the discharge fluid lines, and configured to distribute the reaction gas to the discharge fluid lines; a first side region of the interior of the heating furnace on a first side of the interior of the heating furnace with respect to the first direction; and a second side region of the interior of the heating furnace on a second side of the interior of the heating furnace with respect to the first direction. At least one among the discharge fluid lines may have different flow rates of reaction gas discharged for the first side region and the second side region, and the gas distributor may be configured to distribute the reaction gas to the discharge fluid lines such that flow rates of the discharge fluid lines are different.

According to one or more example embodiments, a wafer processing apparatus, may include: a heating furnace configured to contain wafers disposed along a first direction; flow rate adjusters configured to adjust a flow rate of a raw gas for a reaction processing of the wafers; a mixing fluid line connected to the flow rate adjusters and configured to flow a reaction gas, the reaction gas including a mixture of raw gases; and a gas distributor connected to the mixing fluid line, and configured to distribute the reaction gas to discharge fluid lines. At least parts of the discharge fluid lines may be in an interior of the heating furnace, and discharge the reaction gas distributed from the gas distributor into the interior of the heating furnace, and at least one of discharge fluid lines may have different flow rates of the reaction gas discharged for regions disposed along the first direction in the interior of the heating furnace.

According to one or more example embodiments, a method of using a wafer processing apparatus, the wafer processing apparatus including a heating furnace configured to contain wafers disposed along a first direction, discharge fluid lines configured to discharge a reaction gas into an interior of the heating furnace, and a gas distributor connected to the discharge fluid lines and configured to distribute the reaction gas to the discharge fluid lines, wherein the gas distributor is configured to distribute the reaction gas to the discharge fluid lines such that flow rates of the discharge fluid lines are different, the method may include: a distribution ratio determining operation of determining a distribution ratio of the gas distributor configured to distribute the reaction gas to the discharge fluid lines, and distributing the reaction gas to the discharge fluid lines through the gas distributor according to the distribution ratio; and a wafer processing operation of discharging the reaction gas into the interior of the heating furnace through the discharge fluid lines and performing a reaction processing of the wafers.

### BRIEF DESCRIPTION OF THE DRAWINGS

Embodiments will be more clearly understood from the following detailed description taken in conjunction with the accompanying drawings in which:

FIG. 1 is a drawing showing a supply process of the reaction gas in a wafer processing apparatus according to in one or more embodiments, interior of the heating furnace;

FIG. 2 is a drawing showing a plurality of wafers disposed in an interior of the heating furnace according to one or more embodiments;

FIG. 3 is a drawing showing a discharge fluid line discharging the reaction gas into an interior of the heating furnace, according to one or more embodiments;

FIG. 4 is a drawing showing a plurality of discharge fluid lines connected to a gas distributor, according to one or more embodiments;

FIG. 5 is a drawing showing a configuration in which a plurality of gas distributors are provided, according to one or more embodiments;

FIG. 6 is a graph showing a result of supplying the reaction gas at the same flow rate to each region of the heating furnace according to one or more embodiments;

FIG. 7 is a graph showing a result of improving thickness deviation of wafers through a plurality of discharge fluid lines, according to one or more embodiments;

FIG. 8 is a drawing conceptually showing a configuration in which an interior of the heating furnace is divided into a first side region and second side region, according to one or more embodiments;

FIG. 9 is a drawing showing a configuration of supplying the reaction gas into an interior of the heating furnace by using a first discharge fluid line and a second discharge fluid line, according to one or more embodiments;

FIG. 10 is a drawing showing a discharging hole provided in the first discharge fluid line and the second discharge fluid line of FIG. 9 according to one or more embodiments;

FIG. 11 is a graph showing a process of improving a thickness deviation of a wafer by supplying the reaction gas by the first discharge fluid line and the second discharge fluid line of FIG. 9 according to one or more embodiments;

FIG. 12 is a drawing conceptually showing a configuration in which the interior of the heating furnace is divided into a first side region, a second side region, and a central region, according to one or more embodiments;

FIG. 13 is a drawing showing a configuration of supplying the reaction gas into an interior of the heating furnace by using the first discharge fluid line, the second discharge fluid line, and the third discharge fluid line, according to one or more embodiments;

FIG. 14 is a drawing showing a discharging hole provided in the first discharge fluid line, the second discharge fluid line, and the third discharge fluid line of FIG. 13 according to one or more embodiments;

FIG. 15 is a graph showing a process of improving a thickness deviation of a wafer by supplying the reaction gas by the first discharge fluid line, the second discharge fluid line, and the third discharge fluid line of FIG. 13 according to one or more embodiments;

FIG. 16 is a graph showing a process of improving a thickness deviation of a wafer by correcting a distribution ratio between a plurality of discharge fluid lines, according to according to one or more embodiments; and

FIG. 17 is a flowchart showing a method of using a wafer processing apparatus according to one or more embodiments.

### DETAILED DESCRIPTION

In the following detailed description, only certain embodiments of the present disclosure have been shown and described, simply by way of illustration.

As those skilled in the art would realize, the described embodiments may be modified in various different ways, all without departing from the spirit or scope of the present disclosure. Accordingly, the drawings and description are to be regarded as illustrative in nature and not restrictive. Like reference numerals designate like elements throughout the specification.

In the present specification, duplicate descriptions for the same components are omitted.

Also, in present specification, it is to be understood that when one component is referred to as being “connected” or “coupled” to another component, it may be connected or coupled directly to the other component or be connected or coupled to another component with the other component intervening therebetween. On the other hand, in this specification, it is to be understood that when one component is referred to as being “connected or coupled directly” to another component, it may be connected or coupled to the other component without another component intervening therebetween.

It is also to be understood that the terminology used herein is only for the purpose of describing particular embodiments, and is not intended to be limiting of the disclosure.

Singular forms are to include plural forms unless the context clearly indicates otherwise.

It will be further understood that term “comprises” or “have” used in the present specification specify the presence of stated features, numerals, steps, operations, components, parts, or a combination thereof, but does not preclude the presence or addition of one or more other features, numerals, steps, operations, components, parts, or a combination thereof.

Also, as used herein, the term “and/or” includes any plurality of combinations of items or any of a plurality of listed items. In this specification, “A or B” may include “A”, “B”, or “A and B”.

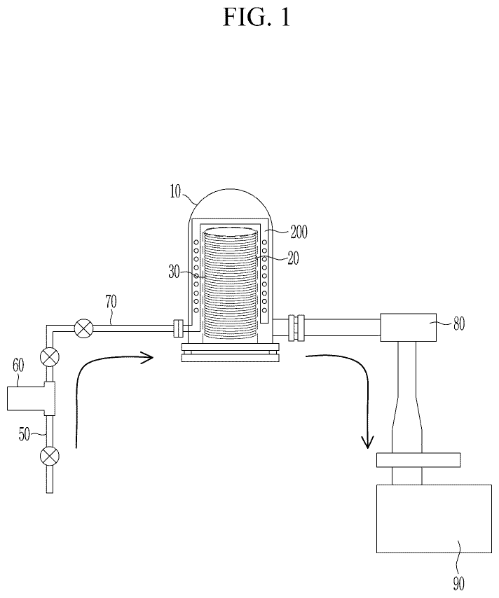

FIG. 1 is a drawing showing a flow process of the reaction gas in a wafer processing apparatus 1 according to in one or more embodiments.

The wafer processing apparatus 1 may include a heating furnace 10. A plurality of wafers 30 may be disposed along a first direction X inside the heating furnace 10. FIG. 1 illustrates a configuration in which the plurality of wafers 30 are stacked along a height direction of the heating furnace 10, but the first direction X in which the wafers 30 disposed is not necessarily the height direction of the heating furnace 10.

The wafers 30 may be introduced into an interior of the heating furnace 10 through a boat 20. The plurality of wafers 30 may be disposed on the boat 20 along the first direction X, and the boat 20 may be introduced into the interior of the heating furnace 10.

A discharge fluid line 200 may be provided in the heating furnace 10. The discharge fluid line 200 may be provided in a plural quantity, and may have at least a part located in the interior of the heating furnace 10 and be configured to discharge the reaction gas into the interior of the heating furnace 10.

In more detail, various raw gases for a diffusion process of the wafer 30 may be prepared, and the raw gas may be mixed to form the reaction gas that reacts with the wafer 30. The raw gas may flow along a raw gas fluid line 50, and a flow rate adjuster 60 for adjusting a flow rate of the raw gas may be provided on the raw gas fluid line 50.

The raw gas may have various types, and the various types of the raw gases may flow through different raw gas fluid lines 50. The flow rate adjuster may be provided in a plurality of raw gas fluid lines 50, respectively, for controlling its flow.

Meanwhile, a plurality of flow rate adjusters 60 may be connected to one mixing fluid line 70 together. That is, a plurality of raw gases may flow toward the heating furnace 10 along the single mixing fluid line 70. For better understanding and ease of description, the gas in a mixed form of the plurality of raw gases that are mixed while flowing along the mixing fluid line 70 is referred to the reaction gas.

The discharge fluid line 200 may flow the reaction gas transferred from the mixing fluid line 70, and may discharge the reaction gas into the interior of the heating furnace 10. The reaction gas may react with the wafer 30 in a high temperature environment, and the diffusion process may be performed. That is, the wafer 30 may be subjected to with the reaction processing by the reaction gas in the interior of the heating furnace 10.

After or during the processing of the wafer 30, the reaction gas existing in the heating furnace 10 may be discharged outside the heating furnace 10 through a recollecting fluid line 80. For recollection of the reaction gas, a recollecting pump 90 may be connected in the recollecting fluid line 80.

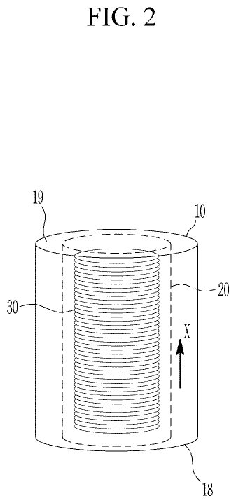

FIG. 2 schematically illustrates a configuration in which the boat 20 in which the plurality of wafers 30 are disposed along the first direction X introduced into the interior of the heating furnace 10.

The boat 20 may include a seating space where the wafers 30 may be seated along the first direction X, and may be introduced into the interior of the heating furnace 10. The boat 20 may be provided such that entry of the reaction gas into and exit of the reaction gas from the interior of the heating furnace 10 are free since the seating space where the wafer 30 is seated is open.

The first direction X in which the plurality of wafers 30 is stacked may vary. For example, as shown in FIG. 2, the plurality of wafers 30 may be a direction from a first side 18 of the heating furnace 10 to a second side 19. As described above, the first direction X may correspond to the height direction of the heating furnace 10, but is not limited thereto.

The plurality of wafers 30 may be loaded on the boat 20 and moved to the interior of the heating furnace 10, and after being subjected to the reaction processing in the interior of the heating furnace 10, the boat 20 may be taken out from the heating furnace 10 and then moved.

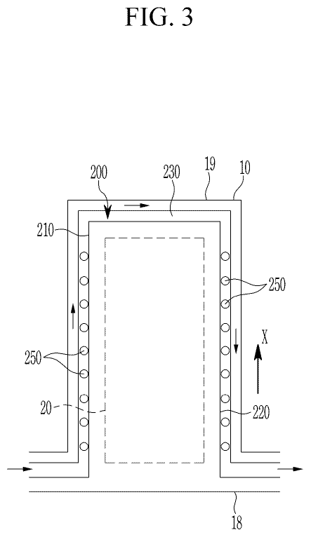

FIG. 3 illustrates the discharge fluid line 200 discharging the reaction gas into the interior of the heating furnace 10.

In one or more embodiments, the discharge fluid line 200 may have at least a portion located in the interior of the heating furnace 10, and may extend to an outer side of the boat 20 and discharge the reaction gas to the interior of the heating furnace 10.

The discharge fluid line 200 may include at least one discharging hole 250 that is open toward the interior of the heating furnace 10. The reaction gas flowing along the discharge fluid line 200 may be discharged to the interior of the heating furnace 10 through the discharging hole 250.

The discharge fluid line 200 may have various extension forms in the interior of the heating furnace 10. For example, the discharge fluid line 200 may include a first extension portion 210 that extends along the first direction X, which is a direction in which the plurality of wafers 30 is disposed.

In the first extension portion 210, a plurality of discharging holes 250 may be disposed along the first direction X, and may overall supply the reaction gas to the plurality of wafers 30 along the first direction X.

In addition, the discharge fluid line 200 may include a second extension portion 220 together with the first extension portion 210. The second extension portion 220 may be disposed in the interior of the heating furnace 10 to be spaced apart from the first extension portion 210 and extend along the first direction X, and may be provided with the plurality of discharging holes 250 arranged along the first direction X.

In one or more embodiments, the discharge fluid line 200 is provided the first extension portion 210 and the second extension portion 220 provided with the plurality of discharging holes 250 as described above, and thereby may increase the discharge area of the discharging hole 250 and the reaction gas and improve the supply of the reaction gas.

The discharge fluid line 200 may further include a connection portion 230 that connects the first extension portion 210 and the second extension portion 220 in the first side 18 in the interior of the heating furnace 10. The discharge fluid line 200 may have a shape that extend in the sequence of the first extension portion 210, the connection portion 230 and the second extension portion 220.

The first extension portion 210 and the second extension portion 220 may extend along the first direction X, that is, between the first side 18 and the second side 19 of the heating furnace 10, and accordingly, the connection portion 230 may be provided to be located on the first side 18 of the heating furnace 10 and connect respective end portions of the first extension portion 210 and the second extension portion 220.

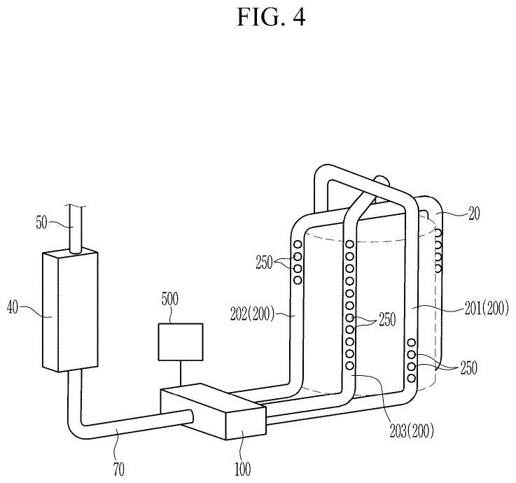

Meanwhile, FIG. 4 illustrates a gas distributor 100 and a plurality of discharge fluid lines 200 provided in the wafer processing apparatus 1 according to one or more embodiments.

In one or more embodiments, the flow rate adjuster 60 may be located inside a gas box 40 shown in FIG. 4. The raw gas fluid line 50 through which the raw gas flows may connected to the gas box 40.

The mixing fluid line 70 through which the reaction gas flows may be drawn out from the gas box 40. The gas distributor 100 may be connected to the plurality of discharge fluid lines 200, and may receive and distribute the reaction gas to each of the plurality of discharge fluid lines 200.

Meanwhile, even if the reaction gas is uniformly supplied to the interior of the heating furnace 10 through the discharge fluid line 200, the density or the like of the reaction gas actually existing in the interior of the heating furnace 10 may be different for each region of the interior of the heating furnace 10 for various reasons.

In other words, even if the reaction gas is evenly supplied to the interior of the heating furnace 10, the plurality of wafers 30 may have the different results of the reaction processing depending on the disposed location. For example, the plurality of wafers 30 may have different thicknesses of the film formed according to the reaction processing, depending on the disposed location.

As described above, in order to prevent a situation in which a thickness deviation occurs in the processing result of the plurality of wafers 30 and it exceeds an allowable value with respect to a predetermined reference value A, in one or more embodiments, the plurality of discharge fluid lines 200 may be provided, and the plurality of discharge fluid lines 200 may have different discharge characteristics of the reaction gas.

For example, in one or more embodiments, at least one among the plurality of discharge fluid lines 200 may have a different flow rate of reaction gas discharged for each of a plurality of regions. That is, as for the discharge fluid lines 200, the region that discharges more reaction gas may be set to be different, and by adjusting a distribution ratio of the reaction gas supplied each discharge fluid line 200, the processing result of the plurality of wafers 30 in the heating furnace 10 may be improved.

The scheme in which the discharge fluid lines 200 are provided such that a discharge flow rate of the reaction gas becomes different depending on regions may vary. For example, at least one among the plurality of discharge fluid lines 200 may be configured such that the number or size of the discharging hole 250 is different for each of the plurality of regions.

For example, as for a first one among the plurality of discharge fluid lines 200, more of the plurality of discharging holes 250 may be located on the first side 18 of the heating furnace 10, and accordingly, the first one among the plurality of discharge fluid lines 200 may discharge more reaction gas to the first side 18 in the interior of the heating furnace 10.

As the discharge fluid lines 200 that discharge more reaction gas to a specific region in the interior of the heating furnace 10 are provided as such, film thickness deviation or the like according to the reaction processing result of the plurality of wafers 30 may be effectively improved.

In one or more embodiments, the gas distributor 100 may be connected to the plurality of discharge fluid lines 200. In addition, the gas distributor 100 may distribute the reaction gas to the plurality of discharge fluid lines 200 such that flow rates of a first one and remaining ones among the plurality of discharge fluid lines 200 are different.

For example, when a film thickness of the wafers 30 located in a central side among the plurality of wafers 30 disposed along the first direction X is to be increased, the gas distributor 100 may increase the distribution ratio of the reaction gas for the discharge fluid line 200 that discharges more reaction gas to the central side.

In one or more embodiments, a controller 500 for the control of the gas distributor 100 may be included. The controller 500 may be provided to adjust the distribution ratio of the gas distributor 100 by controlling the gas distributor 100.

FIG. 4 illustrates a first discharge fluid line 201, a second discharge fluid line 202, and a third discharge fluid line 203 as example of the plurality of discharge fluid lines 200, and as for the first discharge fluid line 201, more of the plurality of discharging holes 250 may be disposed on the first side 18 of the heating furnace 10 in the interior of the heating furnace 10, and as for the second discharge fluid line 202, more of the plurality of discharging holes 250 may be disposed on the second side 19 of the heating furnace 10 in the interior of the heating furnace 10, and as the third discharge fluid line 203, the plurality of discharging holes 250 may be disposed to be evenly dispersed in the interior of the heating furnace 10.

In this case, the wafer processing apparatus 1 according to one or more embodiments may adjust the thickness deviation between the wafer 30 by adjusting a supply flow rate of the reaction gas based on the first direction X in which the wafers 30 are stacked.

For example, when the thickness of the entire plurality of wafers 30 in the reaction processing result of the wafers 30 is out of the allowable value with respect to the predetermined reference value, the result may be improved by adjusting an allowed gas distribution ratio with respect to the third discharge fluid line 203 through the gas distributor 100.

When, in the reaction processing result, the thickness of the wafers 30 located in the first side 18 of the heating furnace 10 among the plurality of wafers is out of the allowable value with respect to the reference value, the result may be improved by adjusting the allowed gas distribution ratio with respect to the first discharge fluid line 201 through the gas distributor 100.

When, in the reaction processing result, the thickness of the wafers 30 located in the second side 19 of the heating furnace 10 among the plurality of wafers is out of the allowable value with respect to the reference value, the result may be improved by adjusting the allowed gas distribution ratio with respect to the second discharge fluid line 202 through the gas distributor 100.

As described above, when the gas distributor 100 and the plurality of discharge fluid lines 200 are provided, the reaction processing result for the plurality of wafers 30 may be effectively improved, and the degree of completion may be effectively improved while processing the plurality of wafers 30 together.

In addition, by adjusting the flow rate of reaction gas of the plurality of discharge fluid lines 200, not by using the flow rate adjuster 60 described above but by using the gas distributor 100, the complexity of the facility may be effectively improved.

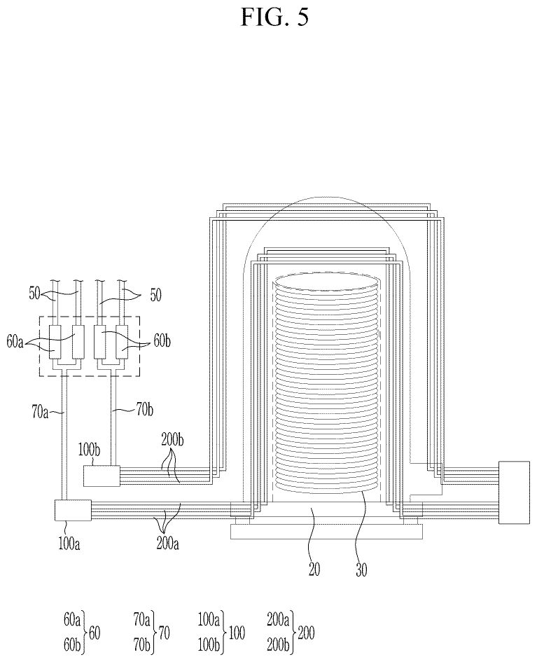

FIG. 5 illustrates the wafer processing apparatus 1 in which the flow rate adjuster 60 is provided to each of the plurality of raw gas fluid lines 50 and the plurality of discharge fluid lines 200 are connected through one gas distributor 100 according to one or more embodiments.

The flow rate adjuster 60 may adjust the flow rate of the raw gas for reaction processing of the wafer 30, and may be provided for each of the raw gas fluid line 50. That is, the plurality of flow rate adjusters 60 may be provided on different raw gas fluid lines 50, to adjust the flow rates of different raw gases.

The mixing fluid line 70 may be connected to the plurality of flow rate adjusters 60 and may flow the reaction gas in which the plurality of raw gases are mixed. In addition, if necessary, the mixing fluid line 70 may be provided in a plural quantity, and a plurality of mixing fluid lines 70 may be connected to different flow rate adjusters 60.

For example, the plurality of flow rate adjusters 60 may be divided into a plurality of groups depending on according to the raw gas characteristics. The mixing fluid line 70 may be provided in a plural quantity, and may include a first mixing fluid line 70a and a second mixing fluid line 70b.

The first mixing fluid line 70a may be connected to a first group 60a among the plurality of flow rate adjusters 60, and the second mixing fluid line 70b may be connected to a second group 60b among the plurality of flow rate adjusters 60.

The grouping of the plurality of flow rate adjusters 60 may be determined according to gas characteristics or the like of the raw gas of which the flow rate is adjusted by the respective flow rate adjuster 60. For example, the flow rate adjusters 60, among the plurality of raw gases, configured to adjust the flow rate of the active gas may be grouped as the first group 60a and connected to the first mixing fluid line 70a, and the flow rate adjusters 60 configured to adjust the flow rate of the inert gas may be grouped as the second group 60b and connected to the second mixing fluid line 70b.

That is, the first mixing fluid line 70a and the second mixing fluid line 70b may flow different reaction gases. Through this, mixing or the like between active gases and inert gases in the flow process may be prevented while decrease the number of fluid lines extending toward the heating furnace 10 to be lower than the number of the raw gas.

The gas distributor 100 may be connected to the mixing fluid line 70, and may distribute the reaction gas supplied from the corresponding mixing fluid line 70 to the plurality of discharge fluid lines 200. For example, in one or more embodiments, the gas distributor 100 may be provided in a plural quantity, and a first gas distributor 100a may be connected to the first mixing fluid line 70a, and a second gas distributor 100b may be connected to the second mixing fluid line 70b.

The first gas distributor 100a may be connected to a first group 200a among the plurality of discharge fluid lines 200, and the second gas distributor 100b may be connected to a second group 200b among the plurality of discharge fluid lines 200. The first group 200a of the plurality of discharge fluid lines 200 may be connected to the first gas distributor 100a and supplied with the reaction gas, and the second group 200b of the plurality of discharge fluid lines 200 may be connected to the second gas distributor 100b and supplied with the reaction gas.

As for the plurality of discharge fluid lines 200 connected to the same gas distributor 100, the reaction gas discharged to the interior of the heating furnace 10 the may be the same as each other. The first group 200a of the plurality of discharge fluid lines 200 may discharge a different reaction gas from the second group 200b among the plurality of discharge fluid lines 200.

In one or more embodiments, as described above, even if the plurality of discharge fluid lines 200 that discharge the different flow rate of reaction gas depending on the plurality of regions is provided, by adjusting the distribution ratio by using the single gas distributor 100 without the flow rate adjuster 60 for the flow control of each of the discharge fluid line 200, simplification of the facility and supply of the reaction gas for each region may be efficiently achieved.

In more detail, when the gas distributor 100 and the mixing fluid line 70 are omitted, the plurality of discharge fluid lines 200 needs to be branched for each raw gas fluid line 50, and the flow rate adjuster 60 is required for each discharge fluid line 200, thereby increasing the complexity of the facility.

In addition, even if the plurality of raw gas fluid lines 50 are integrated and streamlined through the mixing fluid line 70, the plurality of mixing fluid lines 70 may be needed depending on the gas characteristics or the like, and accordingly, the plurality of discharge fluid lines 200 are branched from each of the plurality of mixing fluid lines 70, thereby excessively increasing the required number of the flow rate adjuster 60.

On the other hand, the wafer processing apparatus 1 according to one or more embodiments is beneficial because, by using the gas distributor 100, a complicated change of the facility is not caused while the plurality of discharge fluid lines 200 is flow-controlled integratedly.

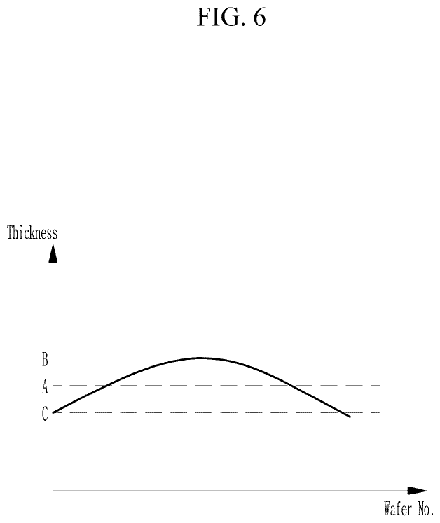

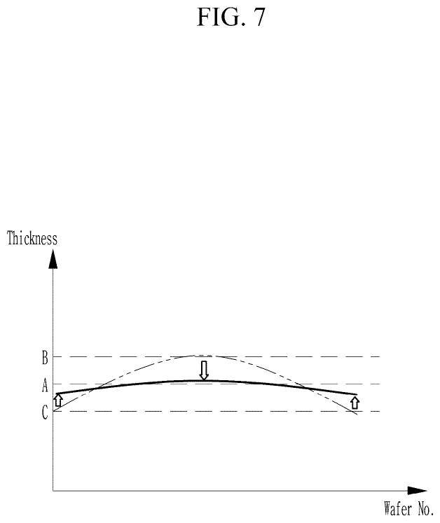

Meanwhile, FIG. 6 is a graph representing the thickness measurement value of the plurality of wafers 30 measured when the reaction gas is evenly discharged into the interior of the heating furnace 10 through the single discharge fluid line 200, and FIG. 7 is a graph showing the improved thickness measurement value graph of the plurality of wafers 30 obtained by adjusting the reaction gas supplied to the interior of the heating furnace 10 through the plurality of discharge fluid lines 200.

The horizontal axis in the graphs of FIG. 6 and FIG. 7 represents the arrangement number of the wafers 30. Based on the first direction X in which the wafers 30 is disposed, the position number may increase away from the wafer 30 nearest to the first side 18 of the heating furnace 10. The vertical axis represents a thickness value of each wafer 30.

As well as the graphs of FIG. 6 and FIG. 7, the meaning of the horizontal axis and the vertical axis of all graphs explained hereinafter is the same.

First, referring to FIG. 6, when the interior of the heating furnace 10 is not divided into regions or the like and evenly supplied with the reaction gas overall, the thickness value deviation between may occur, and some wafers 30 may become out of the allowable value with respect to the reference value A.

There may be various causes for the thickness value deviation as above. For example, the continuous supply of the reaction gas in the processing process of the wafer 30 may cause concentration of the reaction gas at a central side between the first side 18 and the second side 19 in the heating furnace 10, and accordingly, a maximum thickness value B may be found in the wafers 30 of the central side.

In addition, as described above, the recollecting fluid line 80 for recollecting the reaction gas in the interior of the heating furnace 10 may be connected to the first side 18 or the second side 19 of the heating furnace 10, and due to the effect of the negative pressure generated by the recollecting pump 90, the amount of the reaction gas decreases at the first side 18 or the second side 19, and accordingly, a minimum thickness value C of the wafer 30 may be found in the wafer 30 located on the first side 18 or the second side 19.

According to various causes described above, the thickness value of the wafers 30 mainly disposed on the central side in the processing process of the wafers 30 stacked along the first direction X may relatively increase, and the thickness value of the wafers 30 disposed on the outer boundary side may relatively decrease.

FIG. 7 illustrates a graph showing improvement of obtained a thickness value deviation of the wafers 30 by changing supply characteristics of the reaction gas.

Referring to FIG. 7, in order to compensate a decrease of the thickness value of the wafers 30 at the outer boundary side, the reaction gas flow rate ratio supplied to the first side 18 and the second side 19 of the heating furnace 10 may be increased, and through this, the thickness value of the wafers 30 located on the first side 18 and the second side 19 of the heating furnace 10 may be increased to correspond to the reference value A.

In addition, in order to compensate an increase of the thickness value increase of the wafers 30 at the central side, the reaction gas flow rate ratio supplied to the central side of the heating furnace 10 may be decreased, and through this, the thickness value of the wafers 30 located on the central side of the heating furnace 10 may be decreased to correspond to the reference value A. Here, the total amount of the reaction gas supplied to the heating furnace 10 is not necessarily changed.

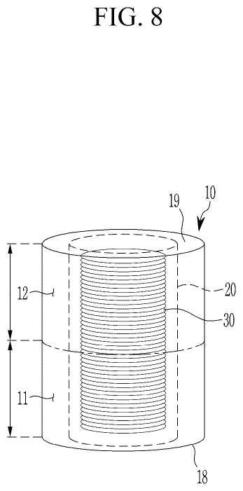

FIG. 8 illustrates a configuration in which the interior of the heating furnace 10 is divided into a first side region 11 and a second side region 12 according to one or more embodiments. The interior of the heating furnace 10 may be divided into the plurality of regions along the first direction X.

The plurality of regions may include the first side region 11 located on the first side 18 in the interior of the heating furnace 10 and the second side region 12 located on the second side 19 in the interior of the heating furnace 10, based on the first direction X.

The first side region 11 may be defined to include the first side 18 of the heating furnace 10, and the second side region 12 may be defined to include the second side 19 of the heating furnace 10. Boundary of the first side region 11 and the second side region 12 may be set in various ways as needed.

For example, the boundary may be defined based on a right center between the first side 18 and the second side 19 of the heating furnace 10, may be defined based on the wafer 30 disposed in the right center among the wafers 30 stacked from the first side 18 of the heating furnace 10 toward the second side 19, and such a boundary may be changed as needed.

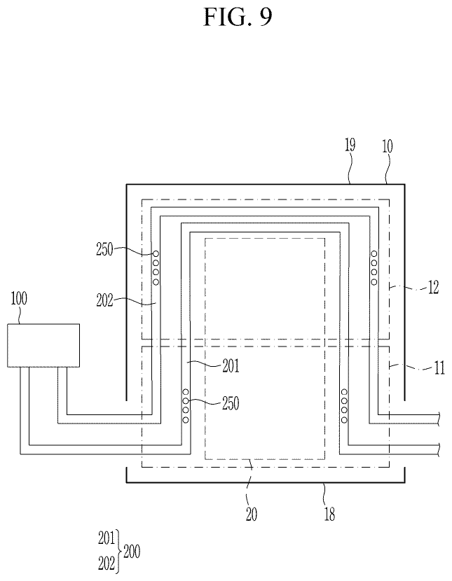

FIG. 9 illustrates a configuration in which the interior of the heating furnace 10 is divided into the first side region 11 and the second side region 12 and that is provided with the plurality of discharge fluid lines 200 configured to discharge more reaction gas to each region.

As an example, the plurality of discharge fluid lines 200 may include the first discharge fluid line 201 and the second discharge fluid line 202. As for the first discharge fluid line 201, the flow rate of the reaction gas discharged to the first side region 11 may be greater than the flow rate of the reaction gas discharged to the second side region 12.

As for the second discharge fluid line 202, the flow rate of the reaction gas discharged to the second side region 12 may be greater than the flow rate of the reaction gas discharged to the first side region 11. Even in this case, if necessary, the third discharge fluid line 203 that evenly supplies the reaction gas to all of the first side region 11 and the second side region 12 may be included.

The first discharge fluid line 201 and the second discharge fluid line 202 may be connected to the gas distributor 100, and the gas distributor 100 may distribute and supply the reaction gas to the first discharge fluid line 201 and the second discharge fluid line 202.

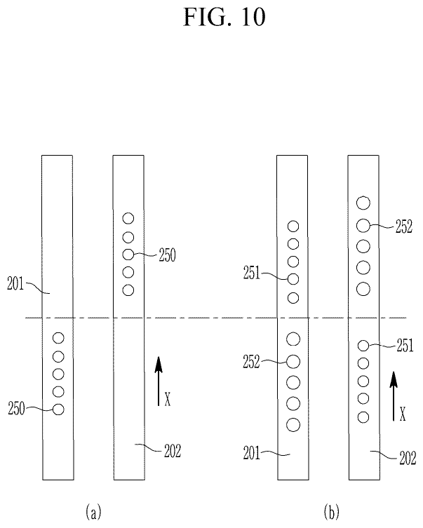

FIG. 10 illustrates various configurations of the discharging holes 250 with respect to the first discharge fluid line 201 and the second discharge fluid line 202, when the first discharge fluid line 201 and the second discharge fluid line 202 are provided in the interior of the heating furnace 10 as shown in FIG. 9.

Referring to FIG. 10(a), as for the first discharge fluid line 201, the discharging hole 250 may be provided only at locations corresponding to the first side region 11, and as for the second discharge fluid line 202, the discharging hole 250 may be provided only at locations corresponding to the second side region 12.

Referring to FIG. 10(b), as for the first discharge fluid line 201, the number of the discharging holes 250 provided in the first side region 11 may be greater than that in the second side region 12, or at least one first discharging hole 251 may be provided in the second side region 12 and at least one second discharging hole 252 having a greater diameter than the first discharging holes 251 may be provided in the first side region 11.

As for the second discharge fluid line 202, the number of the discharging holes 250 provided in the second side region 12 may be greater than that in the first side region 11, or the at least one first discharging hole 251 may be provided in the first side region 11 and at least one second discharging hole 252 having a great diameter than the first discharging holes 251 may be provided in the second side region 12.

The feature of the first discharge fluid line 201 and the second discharge fluid line 202 shown in FIG. 10 is merely one of various examples that can enable the flow rate of the reaction gas discharged to the first side region 11 and the second side region 12 to be different, and various modifications may be available as needed.

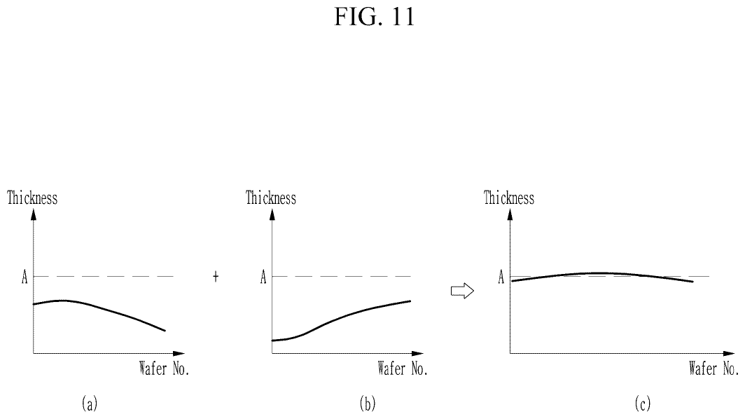

FIG. 11 is a graph conceptually representing the method of improving the thickness value of the wafers 30 through the flow rate of reaction gas adjustment, when the first discharge fluid line 201 and the second discharge fluid line 202 are provided in the interior of the heating furnace 10 as in FIG. 9.

FIG. 11(a) is a graph representing the thickness value of the wafers 30 subjected to the reaction processing by supplying the reaction gas only through the first discharge fluid line 201, FIG. 11(b) is a graph representing the thickness value of the wafers 30 subjected to the reaction processing by supplying the reaction gas only through the second discharge fluid line 202, and FIG. 11(c) is a graph representing the thickness value of the wafers 30 subjected to the reaction processing by supplying the reaction gas through all of the first discharge fluid line 201 and the second discharge fluid line 202.

As for the thickness value of the wafer 30, the amount of the reaction gas with respect to the corresponding region may serve as a major factor. Accordingly, when both the first discharge fluid line 201 and the second discharge fluid line 202 are used as in FIG. 11(c), the thickness value of the wafers 30 located in the first side region 11 of the heating furnace 10 may be compensated by adjusting the flow rate of reaction gas of the first discharge fluid line 201, and the thickness value of the wafers 30 located in the second side region 12 of the heating furnace 10 may be compensated by adjusting the flow rate of reaction gas of the second discharge fluid line 202.

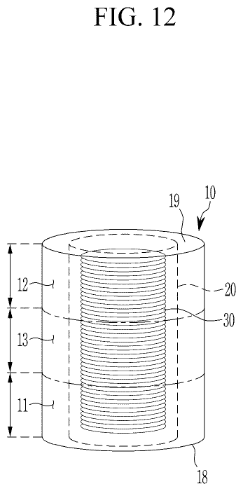

Meanwhile, FIG. 12 illustrates a configuration in which the interior of the heating furnace 10 is divided into the first side region 11, the second side region 12 and a central region 13 according to one or more embodiments.

In the wafer processing apparatus 1, regions of the interior of the heating furnace 10 may be divided and defined in various ways as needed, and in one or more embodiments, when the interior of the heating furnace 10 is divided into the first side region 11, the second side region 12, and the central region 13, the first side region 11 may be located on the first side 18 in the interior of the heating furnace 10 based on the first direction X, the second side region 12 may be located on the second side 19 in the interior of the heating furnace 10 based on the first direction X, and the central region 13 may be located between the first side region 11 and the second side region 12 in the interior of the heating furnace 10.

The first side region 11 may be defined to include the first side 18 of the heating furnace 10, and the second side region 12 may be defined to include the second side 19 of the heating furnace 10. The boundary of the central region 13 with respect to the first side region 11 and the second side region 12 may be set in various ways as needed.

For example, boundaries of the first side region 11, the central region 13 and the second side region 12 may be set by equally dividing a space between the first side 18 and the second side 19 of the heating furnace 10, and the boundary of the first side region 11, the second side region 12, and the central region 13 may be defined by equally dividing the wafers 30 stacked in the heating furnace 10. Such a boundary may be changed as needed.

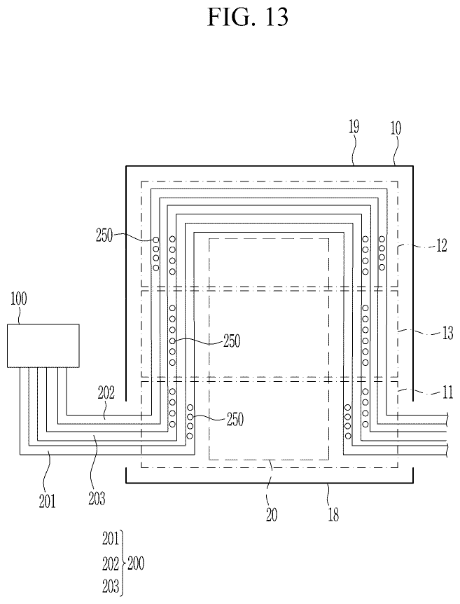

FIG. 13 illustrates a configuration in which the interior of the heating furnace 10 is divided into the first side region 11, the second side region 12, and the central region 13, and that is provided with the plurality of discharge fluid lines 200 configured to discharge the reaction gas to each region.

As an example, the plurality of discharge fluid lines 200 may include the first discharge fluid line 201, the second discharge fluid line 202, and the third discharge fluid line 203. As for the first discharge fluid line 201, the flow rate of the reaction gas discharged to the first side region 11 may be greater than the flow rate of the reaction gas discharged to the second side region 12 and the central region 13.

As for the second discharge fluid line 202, the flow rate of the reaction gas discharged to the second side region 12 may be greater than the flow rate of the reaction gas discharged to the first side region 11 and the central region 13.

As for the third discharge fluid line 203, the flow rate of the reaction gas discharged to the central region 13 may be greater than or equal to the flow rate of the reaction gas discharged to the first side region 11 and the second side region 12.

The first discharge fluid line 201, the second discharge fluid line 202, and the third discharge fluid line 203 may be connected to the gas distributor 100, and the gas distributor 100 may distribute and supply the first discharge fluid line 201, the reaction gas to the second discharge fluid line 202, and the third discharge fluid line 203.

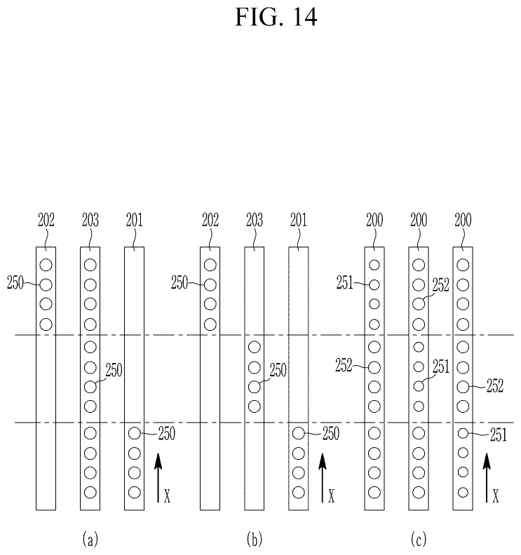

FIG. 14 illustrates various configurations of the discharging holes 250 with respect to the first discharge fluid line 201, the second discharge fluid line 202, and the third discharge fluid line 203, when the first discharge fluid line 201, the second discharge fluid line 202, and the third discharge fluid line 203 are provided in the interior of the heating furnace 10.

Referring to FIG. 14(a), as for the first discharge fluid line 201, the discharging hole 250 may be provided only at locations corresponding to the first side region 11, and as for the second discharge fluid line 202, the discharging hole 250 may be provided only at locations corresponding to the second side region 12. As for the third discharge fluid line 203, the discharging hole 250 may be provided for all including the first side region 11, the second side region 12, and the central region 13.

In this case, as for the third discharge fluid line 203, the flow rate of the reaction gas discharged to the first side region 11, the second side region 12, and the central region 13 may be the same, and the gas distributor 100 may distribute more reaction gas to the third discharge fluid line 203 than the first discharge fluid line 201 and the second discharge fluid line 202. However, as for the third discharge fluid line 203, various modifications may be available in the number, size, or the like of the discharging hole 250 for each region.

Referring to FIG. 14(b), as for the first discharge fluid line 201, the discharging hole 250 may be provided only at locations corresponding to the first side region 11, and as for the second discharge fluid line 202, the discharging hole 250 may be provided only at locations corresponding to the second side region 12. As for the third discharge fluid line 203, the discharging hole 250 may be provided only at locations corresponding to the central region 13.

Meanwhile, FIG. 14(c) illustrates a configuration of the discharging hole 250 that decreases the flow rate of reaction gas with respect to a specific region. Unlike the above-described method, as described above, even if the flow rate of reaction gas of a specific region is decreased, the thickness value adjustment effect of the wafer 30 may be achieved.

For example, in one or more embodiments, a fourth discharge fluid line 200, a fifth discharge fluid line 200, and a sixth discharge fluid line 200 may be provided in the heating furnace 10. As for the fourth discharge fluid line 200, although the discharging hole 250 is present in all of the first side region 11, the second side region 12, and the central region 13, at least one second discharging hole 252 may be provided in the first side region 11 and the central region 13 and at least one first discharging hole 251 having a smaller diameter than the second discharging hole 252 may be provided in the second side region 12. Here, a method in which the discharging hole 250 is removed only in the second side region 12 of the fourth discharge fluid line 200 may also be available.

As for the fifth discharge fluid line 200, although the discharging hole 250 is present in all of the first side region 11, the second side region 12, and the central region 13, the first discharging hole 251 may be provided in the central region 12 and the second discharging hole 252 having a larger diameter than the first discharging hole 251 may be provided in the first side region 11 and the second side region 12. Here, a method in which the discharging hole 250 is removed only in the central region 13 of the fifth discharge fluid line 200 may also be available.

As for the sixth discharge fluid line 200, although the discharging hole 250 is present in all of the first side region 11, the second side region 12, and the central region 13, the first discharging hole 251 may be provided in the first side region 11 and the second discharging hole 252 having a larger diameter than the first discharging hole 251 may be provided in the second side region 12 and the central region 13. Here, a method in which the discharging hole 250 is removed only in the first side region 11 of the sixth discharge fluid line 200 may also be available.

The feature of the discharging hole 250 of the discharge fluid lines 200 shown in FIG. 14 is merely one of various examples that can enable the flow rate of the reaction gas discharged to the first side region 11, the second side region 12, and the central region 13 to be different, and various modifications may be available as needed.

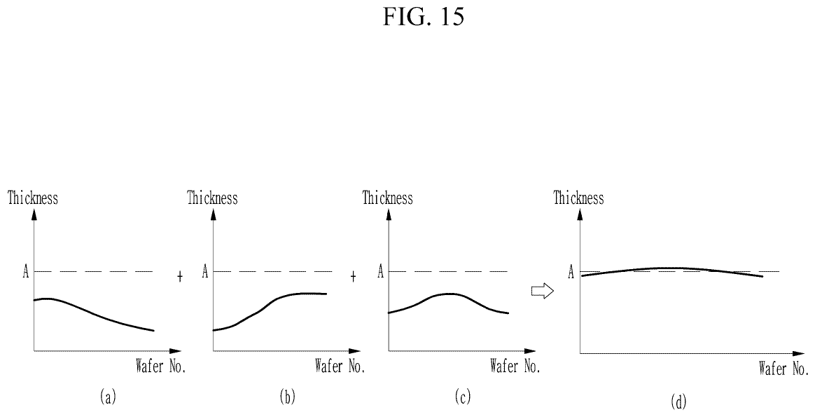

FIG. 15 is a graph conceptually representing the method of improving the thickness value of the wafers 30 through the flow rate of reaction gas adjustment, when the first discharge fluid line 201, the second discharge fluid line 202, and the third discharge fluid line 203 are provided in the interior of the heating furnace 10 as in FIG. 13.

FIG. 15(a) is a graph representing the thickness value of the wafers 30 subjected to the reaction processing by supplying the reaction gas only through the first discharge fluid line 201, FIG. 15(b) is a graph representing the thickness value of the wafers 30 subjected to the reaction processing by supplying the reaction gas only through the second discharge fluid line 202, FIG. 15(c) is a graph representing the thickness value of the wafers 30 subjected to the reaction processing by supplying the reaction gas only through the third discharge fluid line 203, and FIG. 15(d) is a graph representing the thickness value of the wafers 30 subjected to the reaction processing by supplying the reaction gas through all of the first discharge fluid line 201, the second discharge fluid line 202, and the third discharge fluid line 203.

When both the first discharge fluid line 201, the second discharge fluid line 202, and the third discharge fluid line 203 are used as in FIG. 15(d), the thickness value improvement of the wafer 30 with respect to each region may be achieved more effectively.

For example the thickness value of the wafers 30 located in the first side region 11 of the heating furnace 10 may be compensated by adjusting the flow rate of reaction gas of the first discharge fluid line 201, and the thickness value of the wafers 30 located in the second side region 12 of the heating furnace 10 may be compensated by adjusting the flow rate of reaction gas of the second discharge fluid line 202, and the thickness value of the wafers 30 located in the central region 13 of the heating furnace 10 may be compensated by adjusting the flow rate of reaction gas of the third discharge fluid line 203.

The reaction gas of the third discharge fluid line 203 has a great influence on the first side region 11 and the second side region 12 due to the characteristics of the central region 13, and accordingly, the distribution ratio of the first discharge fluid line 201 and the second discharge fluid line 202 may be determined in a state where the reaction gas distribution ratio of the third discharge fluid line 203 is determined to be the highest.

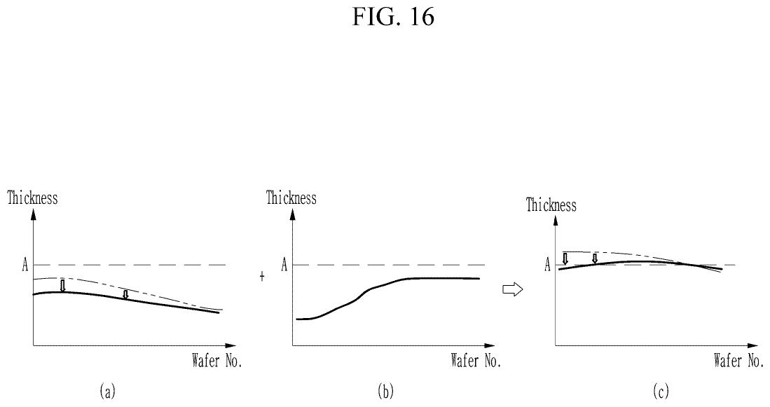

Meanwhile, FIG. 16 is a graph representing the process of correcting the distribution ratio of the gas distributor 100 according to the thickness value measurement result of the wafer 30, in one or more embodiments.

In one or more embodiments, the gas distributor 100 may be capable of adjusting the distribution ratio of the reaction gas with respect to the plurality of discharge fluid lines 200, and the distribution ratio adjustment of the gas distributor 100 may be performed by a worker or performed by the above-described controller 500.

For example, in one or more embodiments, the controller 500 may receive each thickness measurement value of the plurality of wafers 30 for which the reaction processing is completed in the heating furnace 10, and correct the distribution ratio of the gas distributor 100.

For better understanding and ease of description, the graph of FIG. 16 is illustrated based on a state in which the interior of the heating furnace 10 is divided into the first side region 11 and the second side region 12 as shown in FIG. 9, and the first discharge fluid line 201 and the second discharge fluid line 202 are provided in the interior of the heating furnace 10.

FIG. 16(a) is a graph representing the thickness value of the wafers 30 subjected to the reaction processing by using only the first discharge fluid line 201 that discharges more reaction gas to the first side region 11, FIG. 16(b) is a graph representing the thickness value of the wafers 30 subjected to the reaction processing by using only the second discharge fluid line 202 that discharges more reaction gas to the second side region 12, and FIG. 16(c) is a graph representing the thickness value of the wafers 30 subjected to the reaction processing by using the first discharge fluid line 201 and the second discharge fluid line 202 together.

The thickness value measurement of the wafers 30 by using the single discharge fluid line 200 as in FIG. 16(a) and FIG. 16(b) may be, as in FIG. 16(c), data previously measured prior to the processing process of the wafers 30 by using the plurality of discharge fluid lines 200 or data expected experimentally or theoretically.

The wafers 30 subjected to the reaction processing with the reaction gas under a high temperature in the heating furnace 10 may be drawn out from the heating furnace 10 and their respective thickness values may be measured. The wafers 30 of the subsequent round may be introduced into the heating furnace 10 after the measurement process of the thickness is completed, or the wafers 30 of the subsequent round may be introduced into the heating furnace 10 during the measurement process of the thickness such that the reaction processing may be proceeded.

Meanwhile, in FIG. 16(a) and FIG. 16(c), the thickness value before the correction of the distribution ratio according to one or more embodiments is represented in the dotted line, and the thickness value after the correction of the distribution ratio is represented in the solid line.

It may be confirmed that the thickness value of the wafers 30 located in the first side region 11 of the heating furnace 10 in the thickness value represented by the dotted line in FIG. 16(c) generally exceeds the reference value A. In this case, the reaction gas distribution ratio of the first discharge fluid line 201 supplying more reaction gas to the first side region 11 in the gas distributor 100 may be decreased.

The decrease of the reaction gas distribution ratio of the first discharge fluid line 201 may occur while increasing the reaction gas distribution ratio of the second discharge fluid line 202, or as shown in FIG. 16, a total amount decrease of the reaction gas supplied to the corresponding gas distributor 100 may be accompanied.

In one or more embodiments, after it is identified that the correction is required in n-th processing result of the wafer 30, the correction of the above-described distribution ratio may be reflected in the (n+k)-th processing process of the wafer 30, where k may be 1 or greater.

The data represented by a dotted line in FIG. 16(a) may be data before the n-th correction, and the data represented by the solid line may correspond to data after the (n+k)-th correction. By adjusting the thickness value of the wafers 30 located in the first side region 11, the reaction gas distribution ratio of the second discharge fluid line 202 may be corrected together, and as in FIG. 16(b), the reaction gas distribution ratio of the second discharge fluid line 202 may be maintained to be the same.

As in FIG. 16(a), by adjusting the reaction gas distribution ratio of the first discharge fluid line 201, as represented by the solid line in FIG. 16(c), the processing result of the wafer 30 by using all of the first discharge fluid line 201 and the second discharge fluid line 202 may also be changed to conform to the reference value A.

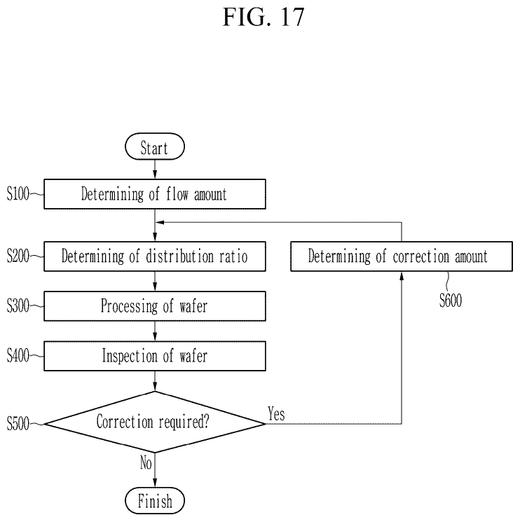

Meanwhile, FIG. 17 is a flowchart showing a method of using the wafer processing apparatus 1 according to one or more embodiments. Hereinafter, referring to FIG. 17, a method of using the wafer processing apparatus 1 according to one or more embodiments will be described, and redundant contents that has been already described in connection with the wafer processing apparatus 1 will be omitted if possible.

A method of using the wafer processing apparatus 1 according to one or more embodiments may include a flow rate determining step S100. In the flow rate determining step S100, by adjusting the above-described flow rate adjuster 60, the flow rate of each raw gas and the flow rate of the reaction gas according thereto may be determined. Such a flow rate determination of the reaction gas may be performed by a worker or the controller 500.

A method of using the wafer processing apparatus 1 according to one or more embodiments may include a distribution ratio determining step S200. In the distribution ratio determining step S200, the distribution ratio of the gas distributor 100 that distributes the reaction gas to the plurality of discharge fluid lines 200 may be determined, and the reaction gas to the plurality of discharge fluid lines 200 may be distributed through the gas distributor 100 according to the distribution ratio. Such determining of the distribution ratio may be performed by a worker or the controller 500.

A method of using the wafer processing apparatus 1 according to one or more embodiments may include a wafer processing step S300. In the wafer processing step S300, the reaction processing of the plurality of wafers 30 may be performed by discharging the reaction gas into the interior of the heating furnace 10 through the plurality of discharge fluid lines 200.

A method of using the wafer processing apparatus 1 according to one or more embodiments may include a wafer inspection step S400. In the wafer inspection step S400, each thickness value of the plurality of wafers 30 subjected to the reaction processing may be inspected after the wafer processing step S300.

The measurement of the thickness value may be performed in the unit of the boat 20, the thickness value measurement may be performed for each of the wafers 30 stacked on the boat 20, and a separate inspection device may be used for the measurement of the thickness value.

A method of using the wafer processing apparatus 1 according to one or more embodiments may include a correction determining step S500. In the correction determining step S500, whether to correct the distribution ratio of the gas distributor 100 may be determined through a difference between each thickness value of the plurality of wafers 30 identified in the wafer inspection step S400 and the predetermined reference value A.

For example, when the deviation of the maximum thickness value B or the minimum thickness value C of the wafers 30 from the reference value A is an allowable value or more, the worker or the controller 500 may determine that the correction of the distribution ratio is necessary.

In addition, even if the deviation between the maximum thickness value B and the minimum thickness value C of the wafers 30 is more than a predetermined reference deviation value, it may be determined that the correction of the distribution ratio is necessary.

In a method of using the wafer processing apparatus 1 according to one or more embodiments, when it is determined in the correction determining step S500 that the correction is not necessary, the processing process of the wafer 30 of the subsequent round may be performed by using the same distribution ratio.

In addition, when it is determined in the correction determining step S50 that the correction is required, a correction amount determining step S600 may be perform. In the correction amount determining step S600, when it is determined in the correction determining step S500 that the distribution ratio is to be corrected, the correction of the distribution ratio amount may be determined through the thickness values of the plurality of wafers 30.

The determination of the correction amount may be determined through comparison with the previously prepared data, or may be determined experimentally or theoretically based on the currently measured deviation.

In the distribution ratio determining step S200, the distribution ratio of the gas distributor 100 may be determined by reflecting the correction amount. For example, when it is determined in the n-th processing result of the wafer 30 that the distribution ratio correction is necessary, the (n+k)-th processing process of the wafer 30 may be performed by reflecting the correction of the distribution ratio.

While the present disclosure has been particularly shown and described with reference to specific embodiments thereof, it will be understood by those skilled in the art that various modifications in form and detail may be made therein without departing from the spirit and scope of the disclosure as defined by the following claims.

### DESCRIPTION OF SYMBOLS

| | |
|---|---|
| 1: wafer processing apparatus | 10: heating furnace |
| 11: first side region | 12: second side region |
| 13: central region | 20: boat |
| 30: wafer | 40: gas box |
| 50: raw gas fluid line | 60: flow rate adjuster |
| 70: mixing fluid line | 80: recollecting fluid line |
| 90: recollecting pump | 100: gas distributor |
| 200: discharge fluid line | 210: first extension portion |
| 220: second extension portion | 230: connection portion |
| 250: discharging hole | 251: first discharging hole |
| 252: second discharging hole | 500: controller |
| S100: flow rate determining step | |
| S200: distribution ratio determining step | |
| S300: wafer processing step | S400: wafer inspection step |
| S500: correction determining step | |
| S600: correction amount determining step | |

What is claimed is:

1. A wafer processing apparatus, comprising:
a heating furnace configured to contain wafers disposed along a first direction;
discharge fluid lines having at least parts in an interior of the heating furnace and configured to discharge a reaction gas into the interior of the heating furnace; and
a gas distributor connected to the discharge fluid lines, and configured to distribute the reaction gas to the discharge fluid lines,
wherein the interior of the heating furnace includes regions divided along the first direction,
wherein at least one among the discharge fluid lines has different flow rates of reaction gas discharged for each of the regions, and
wherein the gas distributor is configured to distribute the reaction gas to the discharge fluid lines such that flow rates of the discharge fluid lines are different.

2. The wafer processing apparatus of claim 1,
wherein the discharge fluid lines comprise discharging holes configured to discharge the reaction gas, and
wherein numbers or sizes of the discharging holes are different for each of the regions.

3. The wafer processing apparatus of claim 1,
wherein the discharge fluid lines comprise a first extension portion extending along the first direction in the interior of the heating furnace,
wherein the first extension portion comprises discharging holes disposed along the first direction and configured to discharge the reaction gas, and
the at least one among the plurality of discharge fluid lines is configured such that numbers or sizes of the discharging holes are different for each of the regions.

4. The wafer processing apparatus of claim 3, wherein the at least one among the plurality of the discharge fluid lines further comprises:
a second extension portion in the interior of the heating furnace, spaced apart from the first extension portion, extending along the first direction, and comprising the discharging holes arranged along the first direction; and
a connection portion connecting the first extension portion and the second extension portion in the first side in the interior of the heating furnace.

5. The wafer processing apparatus of claim 1, wherein the discharge fluid lines are configured to discharge a same reaction gas into the interior of the heating furnace.

6. The wafer processing apparatus of claim 1,
wherein the regions comprises:
a first side region of the interior of the heating furnace on a first side of the interior of the heating furnace with respect to the first direction; and
a second side region of the interior of the heating furnace on a second side of the interior of the heating furnace with respect to the first direction,
wherein the discharge fluid lines comprise:
a first discharge fluid line in which a flow rate of the reaction gas discharged to the first side region is greater than a flow rate of the reaction gas discharged to the second side region; and
a second discharge fluid line in which the flow rate of the reaction gas discharged to the second side region is greater than the flow rate of the reaction gas discharged to the first side region.

7. The wafer processing apparatus of claim 1,
wherein the regions comprises:
a first side region of the interior of the heating furnace on a first side of the interior of the heating furnace with respect to the first direction;
a second side region of the interior of the heating furnace on a second side of the interior of the heating furnace with respect to the first direction; and
a central region between the first side region and the second side region,
wherein the discharge fluid lines comprise:
a first discharge fluid line configured to discharge the reaction gas to the first side region at a flow rate greater than a flow rate of the reaction gas discharged to the second side region and the central region;
a second discharge fluid line configured to discharge the reaction gas to the second side region at a flow rate greater than a flow rate of the reaction gas discharged to the first side region and the central region; and
a third discharge fluid line configured to discharge the reaction gas to the central region at a flow rate greater than or equal to a flow rate of the reaction gas discharged to the first side region and the second side region.

8. The wafer processing apparatus of claim 7,
wherein the third discharge fluid line is configured to discharge the reaction gas to at a same flow rate to the first side region, the second side region, and the central region, and
wherein the gas distributor is configured to distribute more reaction gas to the third discharge fluid line than to the first discharge fluid line and the second discharge fluid line.

9. The wafer processing apparatus of claim 1, further comprising:
flow rate adjusters configured to adjust flow rates of raw gases for reaction processing of the wafers; and
a mixing fluid line connected to the flow rate adjusters and configured to flow the reaction gas, the reaction gas comprising a mixture of the raw gases,
wherein the gas distributor is connected to the mixing fluid line and configured to distribute the reaction gas supplied from the mixing fluid line to the discharge fluid lines.

10. The wafer processing apparatus of claim 9, further comprising:
a plurality of the mixing fluid line comprising a first mixing fluid line connected to a first group among the flow rate adjusters and a second mixing fluid line connected to a second group among the flow rate adjusters; and
a plurality of the gas distributor comprising a first gas distributor connected to the first mixing fluid line and a second gas distributor connected to the second mixing fluid line,
wherein the first group among the discharge fluid lines is connected to the first gas distributor and supplied with the reaction gas, and the second group among the discharge fluid lines is connected to the second gas distributor and supplied with the reaction gas.

11. The wafer processing apparatus of claim 10,
wherein the flow rate adjusters are configured to adjust flow rates of different raw gases, and
wherein the first mixing fluid line and the second mixing fluid line are configured to flow different reaction gases.

12. The wafer processing apparatus of claim 10, wherein the first group among the discharge fluid lines is configured to discharge a different reaction gas than the second group among the discharge fluid lines.

13. The wafer processing apparatus of claim 1, wherein the gas distributor is configured to adjust a distribution ratio of the reaction gas with respect to the discharge fluid lines.

14. The wafer processing apparatus of claim 13, further comprising:
a controller configured to control the gas distributor to adjust the distribution ratio.

15. The wafer processing apparatus of claim 14, wherein the controller is further configured to:
receive thickness measurement values of the wafers completed with a reaction processing in the heating furnace; and
correct the distribution ratio of the gas distributor based on the thickness measurement values.

16. The wafer processing apparatus of claim 1, further comprising:
a boat in which the wafers are disposed along the first direction and configured to be introduced into the interior of the heating furnace.

17. A wafer processing apparatus, comprising:
a heating furnace configured to contain wafers disposed along a first direction;
flow rate adjusters configured to adjust a flow rate of a raw gas for a reaction processing of the wafers;
a mixing fluid line connected to the flow rate adjusters and configured to flow a reaction gas, the reaction gas comprising a mixture of raw gases; and a gas distributor connected to the mixing fluid line, and configured to distribute the reaction gas to discharge fluid lines,
wherein at least parts of the discharge fluid lines are in an interior of the heating furnace, and discharge the reaction gas distributed from the gas distributor into the interior of the heating furnace, and
wherein at least one of discharge fluid lines has different flow rates of the reaction gas discharged for regions disposed along the first direction in the interior of the heating furnace.

18. A method of using a wafer processing apparatus, the wafer processing apparatus comprising a heating furnace configured to contain wafers disposed along a first direction, discharge fluid lines configured to discharge a reaction gas into an interior of the heating furnace, and a gas distributor connected to the discharge fluid lines and configured to distribute the reaction gas to the discharge fluid lines, wherein the gas distributor is configured to distribute the reaction gas to the discharge fluid lines such that flow rates of the discharge fluid lines are different, the method comprising:
a distribution ratio determining operation of determining a distribution ratio of the gas distributor configured to distribute the reaction gas to the discharge fluid lines, and distributing the reaction gas to the discharge fluid lines through the gas distributor according to the distribution ratio; and
a wafer processing operation of discharging the reaction gas into the interior of the heating furnace through the discharge fluid lines and performing a reaction processing of the wafers.

19. The method of claim 18, further comprising:
a wafer inspection operation of, after the wafer processing operation, inspecting thickness values of wafers subjected to the reaction processing; and
a correction determining operation determine whether to correct the distribution ratio of the gas distributor based on a difference between the thickness values of wafers identified in the wafer inspection operation and a predetermined reference value.

20. The method of claim 19, further comprising:
a correction amount determining operation of determining a correction amount of the distribution ratio through the thickness values of wafers, based on the distribution ratio to be corrected,
wherein, in the distribution ratio determining operation, the distribution ratio of the gas distributor is determined by reflecting the correction amount.
